(19) United States
(12) Patent Application Publication
(10) Pub. No.: US 2007/0007566 A1
(43) Pub. Date: Jan. 11, 2007

(54) Semiconductor device having silicide film and method of manufacturing the same

(76) Inventor: Kazunari Ishimaru, Kanagawa-ken (JP)

Correspondence Address: SPRINKLE IP LAW GROUP, 1301 W. 25TH STREET, SUITE 408, AUSTIN, TX, 78705, US

(21) Appl. No.: 11/481,592

(22) Filed: Jul. 6, 2006

(30) Foreign Application Priority Data
Jul. 6, 2005 (JP) P2005-197853

(51) Int. Cl. H01L 29/94

(52) U.S. Cl. 257/295

(57) ABSTRACT

A semiconductor device having a semiconductor substrate, a SRAM area formed in the semiconductor substrate, the SRAM area having first transistors, the first transistor having a metallic compound film formed on each of a source and a drain regions of the first transistor, and a logic circuit area formed in the semiconductor substrate, the logic circuit area having a second transistor, the second transistor having a metallic compound film on each of a source and a drain regions of the second transistor. The thickness of the metallic compound film of the second transistor is thicker than thickness of the metallic compound film of the first transistor.

### BACKGROUND

1. Field of the Invention

The present invention relates to a semiconductor device having silicide film, and to a method of manufacturing the same.

2. Description of the Related Art

In the case of a conventional salicide technique, a source/drain region of a MOS transistor is formed by ion implantation and activation annealing, and thereafter a metallic layer of titanium (Ti), cobalt (Co), nickel (Ni), platinum (Pt) or the like is blanket-deposited on an entire surface of an element region by sputtering or the like. By a subsequent thermal process, a metallic compound film is formed on the element region and on a gate electrode.

If the film thickness of the metallic compound film is made thicker, this makes it possible to reduce the parasitic resistance. However, this causes the metallic compound film to be in contact with a depletion layer expanding from the junction interface, and accordingly the leakage current tends to increase. By contrast, if the film thickness of the metallic compound film is made thinner, this makes it possible to reduce the leakage current. However, the thermal process following the formation of the metallic compound film causes the metallic compound film to flocculate, and this increases the resistance value. In this manner, there is a trade-off relationship between the film thickness and the resistance.

As elements are miniaturized more and more, the capacity of memory integrated in a chip tends to increase. In general, an integrated large-capacity memory is SRAM, and the width (channel width) of an element region of a MOS transistor constituting a SRAM memory cell is almost equal to the minimum line width. Accordingly, the leakage current stemming from the junction tends to increase. A ratio of the leakage current stemming from the SRAM to the total leakage current of an LSI circuit tends to increase. It is an urgent task to reduce the leakage current stemming from the junction, in the memory cell region (memory cell section). For this reason, in the case of the MOS transistor in the memory cell region, it is desired that the film thickness of the metallic compound film to be formed in the element region be made thinner, from a viewpoint of reducing the leakage current stemming from the junction.

On the other hand, channel widths of an MOSFET used for the peripheral circuit region (logic section) are various in size. However, a relatively wider channel width is employed for a circuit which transmits signals to the external, and which receives signals from the external. In the case of such a MOS transistor, it is important that the parasitic capacitance be reduced in order to enhance the current driving capability. For the purpose of reducing the parasitic resistance, it is desired that the film thickness of the metallic compound film be formed thicker.

In the case of a conventional method of forming an LSI circuit and a silicide, only a metallic compound film with a single film thickness is formed. For this reason, the conventional method has offered the following two choices only. One of the choices is that, for the purpose of reducing the leakage current in the memory cell region, the film thickness of the metallic compound film is made thinner, and the performance of a transistor in the peripheral circuit region is sacrificed in exchange. The other choice is that the film thickness of the metallic compound film is made thicker with priority given to the performance, and the leakage current in the memory cell region is accepted.

Consideration can be given to a method of applying the salicide process to each of the memory cell region and the peripheral circuit region. In this case, the salicide process has to be performed twice. In addition, the method is required to include a step of forming a protection film on which of the memory cell region and the peripheral circuit region no salicide process is going to be applied. As a result, this complication of manufacturing steps reduces yields, and accordingly this has hindered semiconductor devices to be provided in an economical manner.

### SUMMARY OF THE INVENTION

One or more of the problems outlined above may be solved by the various embodiments of the invention. Broadly speaking the invention comprises semiconductor device and method of making there of, where the device has salicid metallic compound films.

The invention may be implemented in a variety of ways, and a number of exemplary embodiments will be described in detail bellow.

In one exemplary of the embodiment, a semiconductor device having a semiconductor substrate, a SRAM area formed in the semiconductor substrate, the SRAM area having first transistors, the first transistor having a metallic compound film formed on each of a source and a drain regions of the first transistor, and a logic circuit area formed in the semiconductor substrate, the logic circuit area having a second transistor, the second transistor having a metallic compound film on each of a source and a drain regions of the second transistor. The thickness of the metallic compound film of the second transistor is thicker than thickness of the metallic compound film of the first transistor.

In another exemplary of the embodiment, A method of manufacturing a semiconductor device including, forming a plurality of stripe-shaped element separating films in a substrate in a way that the uppermost portions of the element separating films are higher than the top surface of the substrate, and thereby defining element regions in parts of the top surface of the substrate, the element regions being surrounded by the element separating films, the element regions having first and second element regions, the width of the first element regions and the width of the second element regions being different from each other when measured in a first direction; forming gate electrodes in the first and the second element regions in a way that the gate electrodes extend in the first direction; forming a source and a drain regions in each of the first and the second element regions with corresponding one of the gate electrodes interposed between the source and the drain regions in a direction orthogonal to the first direction; depositing a metallic film on each of the source and drain regions in a direction, which is diagonal to the top surface of the substrate, and whose horizontal component is parallel to the first direction; and causing the substrate and the metallic films to react on each other by thermal processing, and thus forming metallic compound films, which are obtained by the reaction, on upper portions respectively of the source and drain regions.

### BRIEF DESCRIPTION OF THE DRAWINGS

Other objects and advantages of the invention may become apparent upon reading the following detailed description and upon reference to the accompanying drawings.

FIG. 1 is a block diagram of a semiconductor device according to an embodiment of the present invention;

FIG. 2 is a cross-sectional view of the semiconductor device according to the embodiment of the present invention in a second direction thereof;

FIG. 3 is a plan view of the semiconductor device according to the embodiment of the present invention;

FIG. 4 is a cross-sectional view of the semiconductor device according to the embodiment of the present invention, which includes gate electrodes in a first direction thereof (a cross-sectional view of the semiconductor device of FIG. 3 taken in the B-B direction);

FIG. 5 is a cross-sectional view of the semiconductor device according to the embodiment of the present invention, which excludes the gate electrodes in the first direction thereof (a cross-sectional view of the semiconductor device of FIG. 3 taken in the C-C direction);

FIG. 6 is a process cross-section for explaining a method of manufacturing a semiconductor device according to an embodiment of the present invention (a process cross-section of the semiconductor device of FIG. 3 taken in the C-C line);

FIG. 7 is a process cross-section for explaining the method of manufacturing a semiconductor device according to the embodiment of the present invention (a process cross-section of the semiconductor device of FIG. 3 taken in the C-C direction), which follows FIG. 6;

FIG. 8 is a process cross-section for explaining the method of manufacturing a semiconductor device according to the embodiment of the present invention (a process cross-section of the semiconductor device of FIG. 3 taken in the C-C direction), which follows FIG. 7;

FIG. 9 is a process cross-section for explaining the method of manufacturing a semiconductor device according to the embodiment of the present invention (a process cross-section of the semiconductor device of FIG. 3 taken in the C-C direction), which follows FIG. 8;

FIG. 10 is a process cross-section for explaining the method of manufacturing a semiconductor device according to the embodiment of the present invention (a process cross-section of the semiconductor device of FIG. 3 taken in the A-A direction), which follows FIG. 9;

FIG. 11 is a process cross-section for explaining the method of manufacturing a semiconductor device according to the embodiment of the present invention (a process cross-section of the semiconductor device of FIG. 3 taken in the A-A direction), which follows FIG. 10;

FIG. 12 is a process cross-section for explaining the method of manufacturing a semiconductor device according to the embodiment of the present invention (a process cross-section of the semiconductor device of FIG. 3 taken in the A-A direction), which follows FIG. 11;

FIG. 13 is a process cross-section for explaining the method of manufacturing a semiconductor device according to the embodiment of the present invention (a process cross-section of the semiconductor device of FIG. 3 taken in the A-A direction), which follows FIG. 12;

FIG. 14(a) is a process cross-section for explaining the method of manufacturing a semiconductor device according to the embodiment of the present invention (a process cross-section of the semiconductor device of FIG. 3 taken in the A-A direction), which follows FIG. 13;

FIG. 14(b) is a process cross-section for explaining the method of manufacturing a semiconductor device according to the embodiment of the present invention (a process cross-section of the semiconductor device of FIG. 3 taken in the C-C direction), which follows FIG. 13;

FIG. 15 is a process cross-section for explaining the method of manufacturing a semiconductor device according to the embodiment of the present invention (a process cross-section of the semiconductor device of FIG. 3 taken in the A-A direction), which follows FIG. 13;

FIG. 16 is a graph showing an example of the correlation between the thickness of a Ni-sputtered film and the thickness of a Ni silicide film according to the embodiment of the present invention; and

FIG. 17 is a graph showing an example of the correlation between the thickness of the Ni-sputtered film and a leakage current stemming from a junction according to the embodiment of the present invention.

While the invention is subject to various modifications and alternative forms, specific embodiments thereof are shown by way of example in the drawings and the accompanying detailed description. It should be understood, however, that the drawings and detailed description are not intended to limit the invention to the particular embodiments which are described. This disclosure is instead intended to cover all modifications, equivalents and alternatives falling within the scope of the present invention as defined by the appended claims.

### DESCRIPTION OF THE EMBODIMENT

One or more embodiments of the invention are described below. It should be noted that these and any other embodiments described below are exemplary and are intended to be illustrative of the invention rather than limiting.

Hereinafter, descriptions will be provided for embodiments of the present invention by referring to the drawings. In the following descriptions of the drawings, the same or similar reference numerals are used to denote the same or similar components. It should be noted that the drawings are schematic, and that accordingly a relationship between each thickness and each planar dimension in each of the drawings and a ratio in thickness among thicknesses in each of the drawings are different from real ones. For this reason, determination should be made on specific thicknesses and dimensions by taking the following descriptions into consideration. It is a matter of course that the drawings include components whose dimensional relationships and ratios differ from one drawing to another. Furthermore, the embodiments which will be shown hereinafter are employed for the purpose of illustrating a device and methods intended to embody technological concepts concerning the present invention. The technological concepts concerning the present invention do not limit materials, shapes, structures, dispositions and the like of components to what will be described below. Various modifications can be introduced to the technological concepts concerning the present invention within the scope of the claims.

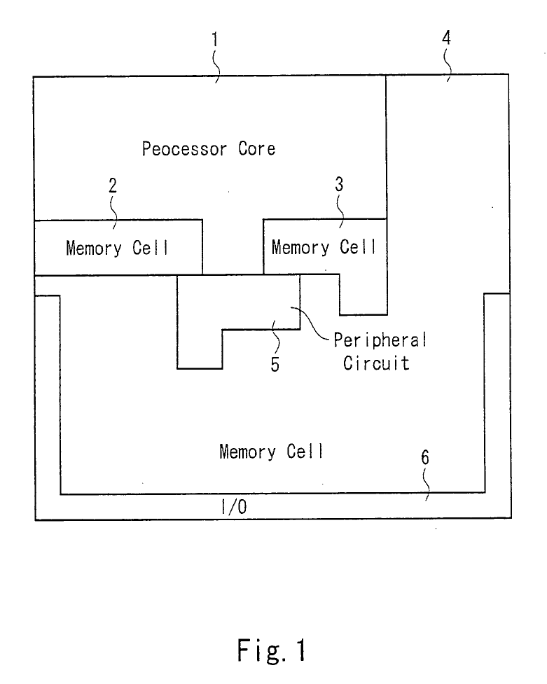

As shown in FIG. 1, the semiconductor device according to an embodiment of the present invention includes, a processor core region 1 which is a logic section for executing a command, memory cell regions 2 to 4 each with a plurality of memory cells; a peripheral circuit region 5 which is a logic section for transmitting signals to and receiving signals from the external, and an I/O region 6 which is an input/output section. The memory cell region 2 is configured, for example, of a SRAM. With regard to the embodiment of the present invention, descriptions will be provided for an insulated-gate type of field-effect transistor (MISFET) constituting the memory cells in the memory cell region 2 and a MISFET constituting the peripheral circuit region (SRAM section) 5.

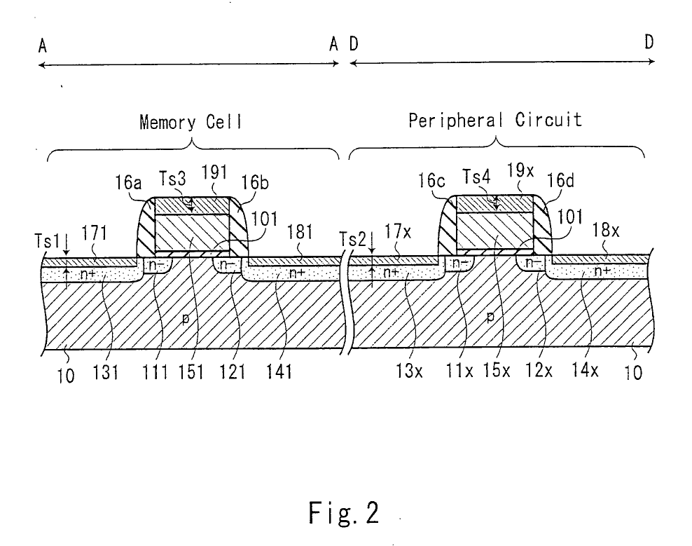

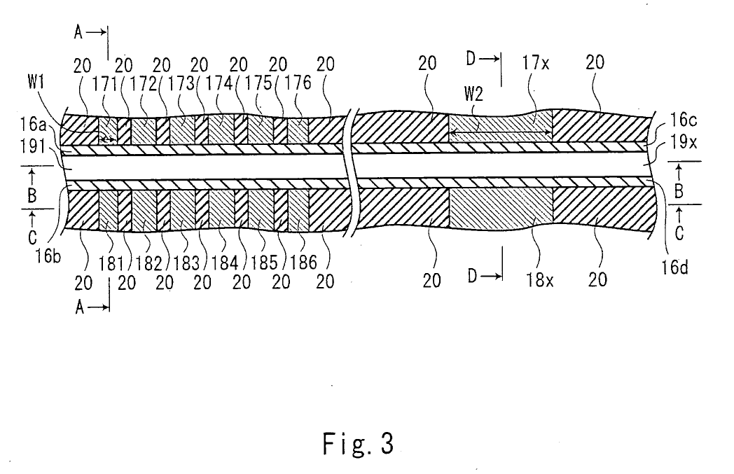

As shown in FIG. 2, the memory cell region 2 includes a MISFET (first transistor) in which metallic compound films 171 and 181 are formed respectively on a source region 131 and a drain region 141. FIG. 2 is cross sectional view of FIG. 3 in A-A direction and D-D direction. The MISFET in the memory cell region 2 includes n− semiconductor regions (extension regions) 111 and 121, which are separate from each other, on a substrate 10; an n+ semiconductor region (source region) 131 and an n+ semiconductor region (drain region) 141, which are disposed in a manner that the extension regions 111 and 121 are interposed between the n+ semiconductor region (source region) 131 and the n+ semiconductor region (drain region) 141, in upper portions of the substrate 10; and a gate electrode 151 disposed above a channel region interposed between the extension regions 111 and 121 with a gate insulating film 101 interposed between the channel region and gate electrode 151.

On the other hand, the peripheral circuit region 5 is formed in and on the same substrate 10 as where the memory cell region 2 is formed. The peripheral circuit region 5 includes a MISFET (second transistor) in which metallic compound films 17x and 18x are formed respectively on a source region 13x and a drain region 14x. The metallic compound films 17x and 18x are respectively thicker than the metallic compound films 171 and 181 in the memory cell region 2. The MISFET in the peripheral circuit region 5 includes n− semiconductor regions (extension regions) 11x and 12x, which are separate from each other, on a substrate 10; an n+ semiconductor region (source region) 13x and an n+ semiconductor region (drain region) 14x, which are disposed in a manner that the extension regions 11x and 12x are interposed between the n+ semiconductor region (source region) 13x and the n+ semiconductor region (drain region) 14x, in upper portions of the substrate 10; and a gate electrode 15x disposed above a channel region interposed between the extension regions 11x and 12x with a gate insulating film 101 interposed between the channel region and gate electrode 15x.

In the MISFETs in the memory cell region 2 and the peripheral circuit region 5, the extension regions 111, 11x, 121 and 12x are regions formed relatively shallower, and having lower impurity concentration, than the source regions 131 and 13x, and the drain regions 141 and 14x, respectively. The MISFETs have structures with lightly doped drains (LDDs). The LDDs are obtained by forming the extension regions 111, 11x, 121 and 12x followed by lightly doping. This enhances MISFET characteristics.

Sidewall insulating films 16a and 16b are disposed on sidewalls of the gate electrodes 151. Sidewall insulating films 16c and 16d are disposed on sidewalls of the gate electrode 15x. For example, a silicon oxide film (SiO2 film), a silicon nitride (Si3N4 film) or the like can be used as material for the sidewall insulating film 16a, 16b, 16c and 16d. In addition to a silicon oxide (SiO2) film which is the same as that used for MOSFETs, silicon nitride (Si3N4), tantalum oxide (Ta2O5), titanium oxide (TiO2), alumina (Al2O3), zirconium oxide (ZrO2), hafnium silicon oxynitride (HfSiON) or the like can be used as material for the gate insulating films 101.

With regard to types of material for the metallic compound films 171, 17x, 181, 18x, 191 and 19x, cobalt silicide (CoSi2), titanium silicide (TiSi2), platinum silicide (PtSi2), tungsten silicide (WSi2), nickel silicide (NiSi2) or the like can be used, for example, in a case where the material for the substrate 10 is silicon (Si).

The metallic compound films 171 and 181 are formed respectively on the source region 131 and the drain region 141. The metallic compound film 191 is formed on the gate electrode 151. In the case where the gate electrode 151 is formed of material containing Si such as polysilicon, a salicide structure is fabricated by forming silicide. The metallic compound films 17x and 18x are formed respectively on the source region 13x and the drain region 14x, and the metallic compound film 19x is formed on the gate electrode 15x. In the case where the gate electrode 15x is formed of material containing Si such as polysilicon, a salicide structure is fabricated by forming silicide. These salicide structures are effective for reducing parasitic resistance in contact portions in the gate electrode 151, the source region 131 and the drain region 141 as well as in contact portions in the gate electrode 15x, the source region 13x and the drain region 14x.

In this respect, the film thickness Ts1 commonly of the metallic compound films 171 and 181 in the memory cell region 2 is smaller than the film thickness Ts2 commonly of the metallic compound films 17x and 18x in the peripheral circuit region 5. It is desirable that, in the memory cell region 2, the film thickness Ts1 commonly of the metallic compound films 171 and 181 be made thinner for the purpose of reducing the leakage current of the transistor stemming from the junction. The film thickness Ts1 commonly of the metallic compound films 171 and 181 is, for example, 2 nm to 20 nm. It is desirable that the film thickness TS1 be 2 nm to 15 nm.

On the other hand, reduction of the parasitic resistance is important for the peripheral circuit region 5. For this reason, it is desirable that the film thickness Ts2 commonly of the metallic compound films 17x and 18x be made thicker. The film thickness Ts2 commonly of the metallic compound films 17x and 18x is, for example, 5 nm to 30 nm. It is desirable that the film thickness Ts2 be 8 nm to 25 nm.

The film thickness Ts3 of the metallic compound film 191 above the gate electrode 151 in the memory cell region 2 is larger than the film thickness Ts1 commonly of the metallic compound films 171 and 181. The film thickness Ts4 of the metallic compound film 19x above the gate electrode 15x in the peripheral circuit region 5 is larger than the film thickness Ts2 commonly of the metallic compound films 17x and 18x. The film thickness Ts3 of the metallic compound film 191 is approximately equal to the film thickness Ts4 of the metallic compound film 19x. The two film thicknesses Ts3 and Ts4 are, for example, 10 nm to 40 nm.

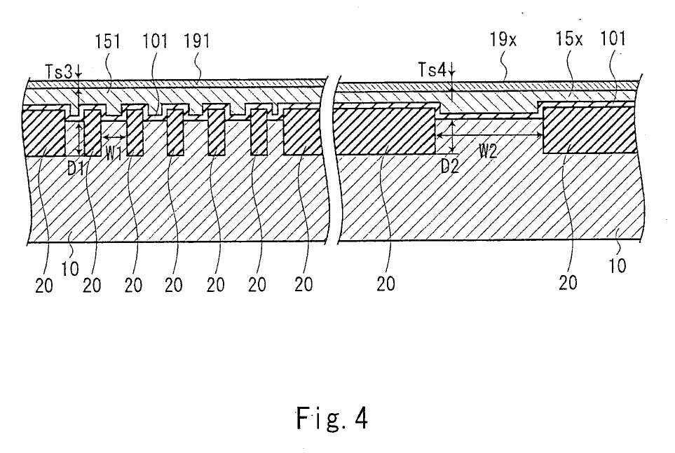

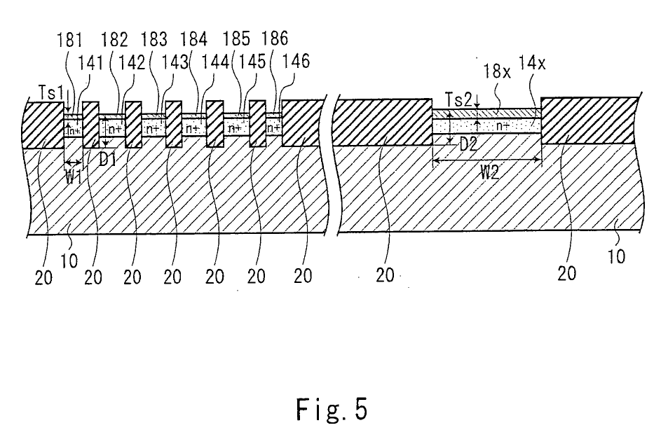

As shown in FIGS. 3 ,4 and 5, the MISFET in the memory cell region 2 and the MISFET in the peripheral cell region 5 are formed in the single substrate 10. FIG. 4 is a cross-sectional view of the semiconductor device according to the embodiment of the present invention, which includes gate electrodes in the direction (a cross-sectional view of the semiconductor device of FIG. 3 taken in the B-B direction). FIG. 5 is a cross-sectional view of the semiconductor device according to the embodiment of the present invention, which excludes the gate electrodes in the direction thereof (a cross-sectional view of the semiconductor device of FIG. 3 taken in the C-C direction). Each element is separated from its adjacent elements with the element-separation insulating films (STI) 20. In the memory cell region 2, a plurality of element regions (hereinafter referred to as “first element regions) are arranged in periodical intervals. The gate electrode 151 extends over the first element regions in a direction in which the first element regions are arranged in periodical intervals (hereinafter referred to as a “first direction”). The width W1 of each of the first element regions in the first direction is smaller than the width W2 of each of the element regions (hereinafter referred to as a “second element region) in the peripheral circuit region 5. The width W1 of each of the first element regions is, for example, 0.01 mm to 0.3 mm. The width W2 of each of the second element regions is, for example, 0.1 mm to 10 mm.

The depth D1 of each first element region from the top surface of the substrate 10 to the bottom of the corresponding element-separation insulating film 20 in the memory cell region 2 is approximately equal to the depth D2 of each second element region from the top surface of the substrate 10 to the bottom of the corresponding element-separation insulating film 20 in the peripheral circuit region 5. The depths D1 and D2 respectively of the element-separation insulating films 20 are, for example, 200 nm to 500 nm.

The semiconductor device shown in FIG. 1 makes it possible to reduce the leakage current stemming from the junction in the memory cell region 2 for which the leakage current stemming from the junction is required to be reduced. This is because the film thickness Ts1 commonly of the metallic compound films 171 and 181 in the memory cell region 2 is relatively smaller than the film thickness Ts2 commonly of the metallic compound films 17x and 18x in the peripheral circuit region 5.

In addition, the film thickness Ts2 commonly of the metallic compound films 17x and 18x in the peripheral circuit region 5 is larger than the film thickness Ts1 commonly of the metallic compound films 171 and 181 in the memory cell region 2. This reduces the resistance in the peripheral circuit region 5. Accordingly, this makes it possible to enhance the current driving capability of the transistor in the peripheral circuit region 5 from which a higher current driving capability is required. In other words, the reduction of the leakage current stemming from the junction of the transistor for which the leakage current stemming from the junction is required to be lower can be compatible with the enhancement of the performance coming from the reduction of the resistance of the transistor from which the higher current driving capability is required.

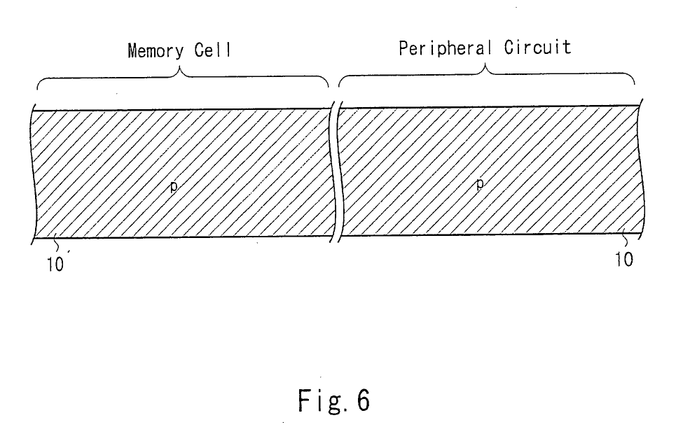

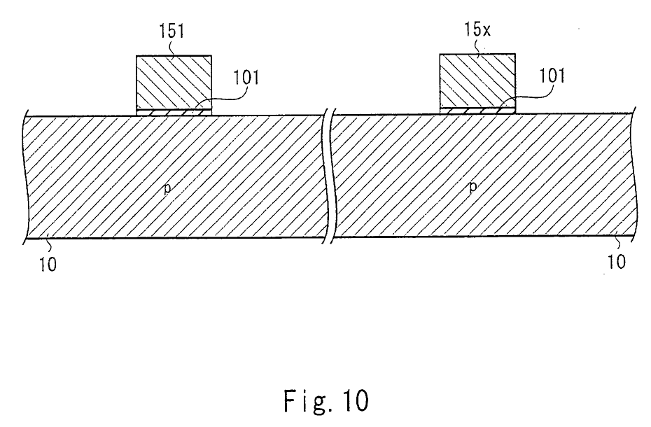

Descriptions will be provided next for a method of manufacturing a semiconductor device according to an embodiment of the present invention by referring to FIGS. 6 to 15. It should be noted that the method of manufacturing a semiconductor device which will be described below is merely an example. It is the matter of course that the present invention can be realized by various other manufacturing methods, including modified examples of this example.

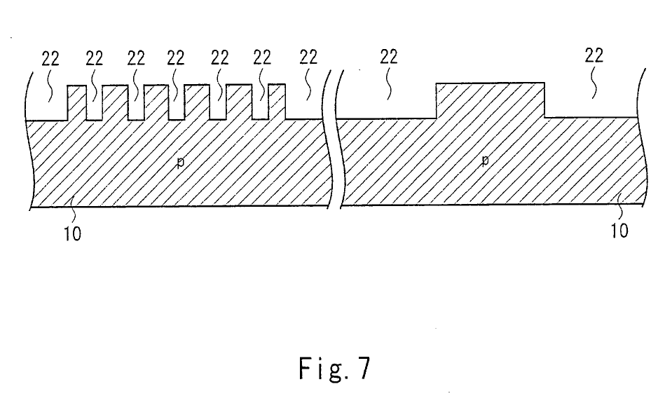

First of all, the substrate 10 such as a Si substrate is prepared, as shown in FIG. 6. A resist film is applied to the top of the substrate 10. The resist film is patterned by use of the lithography technique. The patterned resist film is used as a mask, and thus parts of the substrate 10 are selectively removed from the top surface up to a predetermined depth by reactive ion etching (RIE) or the like. The remaining resist film is removed by use of a resist remover or the like. As a result, a plurality of groove sections are formed as shown in FIG. 7.

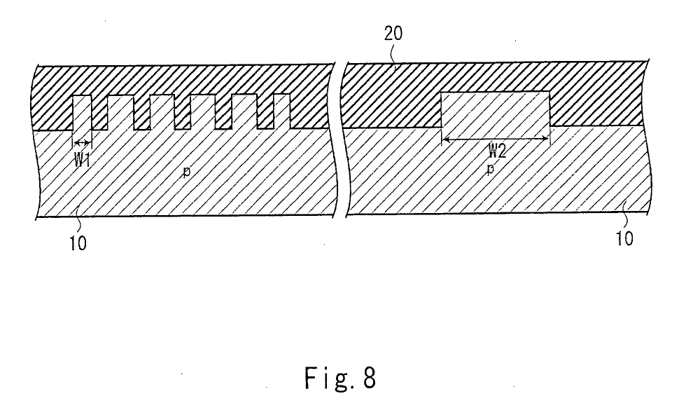

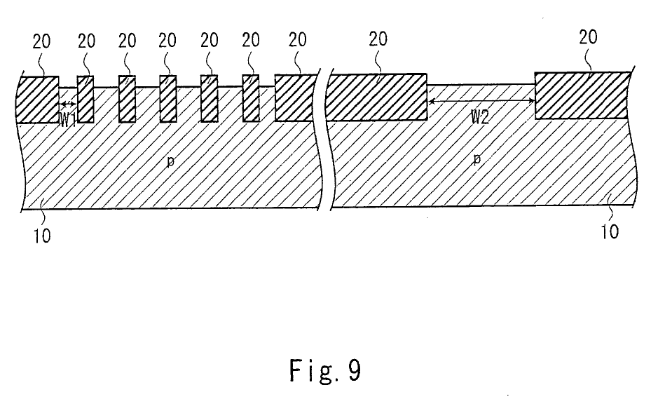

Subsequently, as shown in FIG. 8, an element-separation insulating film 20, which is a SiO2 film or the like, is blanket-deposited on the entire surface by chemical vapor deposition (CVD) or the like. Thereafter, the resultant surface is evened by chemical mechanical polishing (CMP) or the like. Thus, a plurality of stripe-shaped element-separation insulating films 20 are buried in the substrate 10 in a way that the uppermost portions respectively of the element-separation insulating films 20 are higher than the top surface of the substrate 10 , as shown in FIG. 9. Thereby, in the memory cell region 2, parts of the top surface of the substrate 10 are surrounded by the element-separation insulating films 20, and each of the parts of the top surface of the substrate 10 has the width W1 when measured in the first direction These parts are defined as “first element regions.” On the other hand, in the peripheral circuit region 5, parts of the top surface of the substrate 10 are surrounded by the element-separation insulating films 20, and each of the parts of the top surface of the substrate 10 has the width W2, which is larger than the width W1 of each of the first element regions, when measured in the first direction. These parts are defined as “second element regions.” Subsequently, the gate insulating film, which is a SiO2 or the like, is deposited on the top of the resultant substrate 10 by thermal oxidation or the like (the illustration is omitted). After that, a polycrystalline Si film, which will serve as the gate electrode, is deposited on the top of the gate insulating film by low-pressure chemical vapor deposition (LPCVD) or the like. Subsequently, a resist film is applied to the top surface of the polycrystalline Si film, and the resist film is patterned by use of the lithography technique. The patterned resist film is used as a mask, and parts of the polycrystalline Si film and corresponding parts of the gate insulating film are selectively removed by RIE or the like. The remaining resist film is removed by use of a resist remover or the like. As a result, patterns of the gate electrodes 151 and 15x each made of the polycrystalline Si film are formed respectively on the first and the second element regions in a way that the patterns extend in the first direction. In addition, a pattern of the gate insulating film 101 is formed on each of the first and the second element regions in a way that the pattern extends in the first direction.

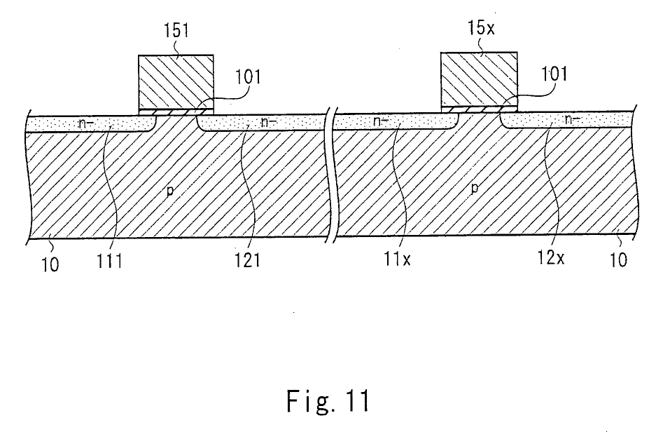

After that, the gate electrodes 151 and 15x are used as masks, and thus n impurity ions such as arsenic (As) ions are implanted to the resultant substrate 10. The remaining resist film is removed by use of a resist remover or the like. Subsequently, the impurity ions are activated by use of RTP. As a result of this, as shown in FIG. 11, the extension region 111 and 121, which have been doped with the impurities, are formed with the gate electrode 151 interposed in between in a direction (hereinafter referred to as a “second direction”) orthogonal to the first direction in the memory cell region 2. In addition, the extension region 11x and 12x which have been doped with the impurities are formed with the gate electrode 15x interposed in between in the second direction in the peripheral circuit region 5.

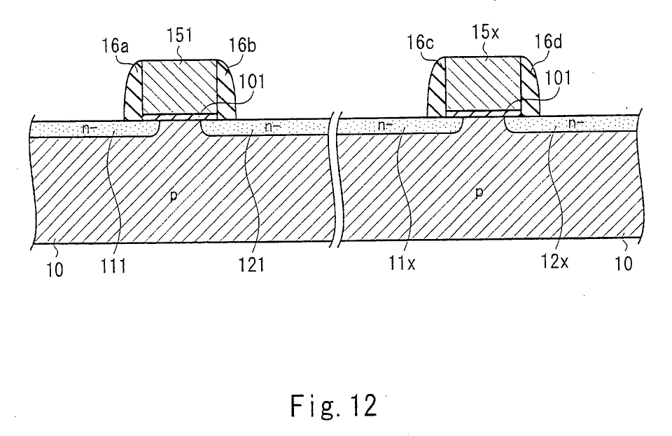

Thereafter, an insulating film, which is a SiO2 film or the like, is deposited on the top surfaces respectively of the resultant substrate 10 and the gate electrodes 151 and 15x by use of LPCVD. Subsequently, parts of the insulating film are selectively removed by orientation-dependent etching, such as RIE, which has an orientation parallel with the sidewalls of each of the gate electrodes 151 and 15x. As a result, as shown in FIG. 12, the top surfaces respectively of the gate electrodes 151 and 15x are exposed. The sidewall insulating films 16a and 16b are formed respectively on the sidewalls of the gate electrode 151. The sidewall insulating films 16c and 16d are formed respectively on the sidewalls of the gate electrode 15x.

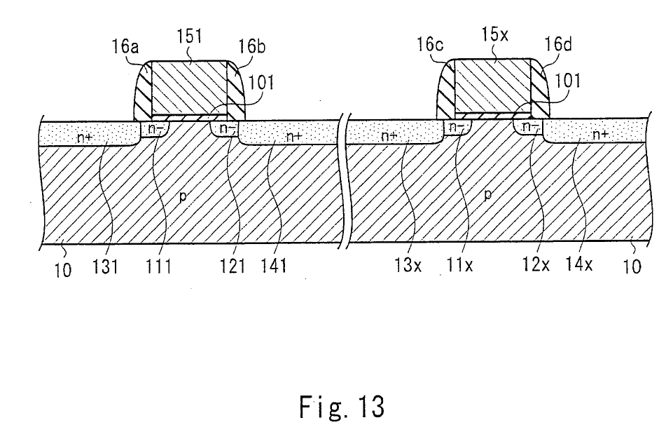

Subsequently, a resist film is applied thereto, followed by patterning. The gate electrodes 151 and 15x as well as the sidewall insulating films 16a, 16b, 16c and 16d are used as masks, and thus n impurities such as phosphorus (P) ions are implanted to the resultant substrate 10. The remaining resist film is removed by use of the resist remover or the like. Thereafter, the impurity ions are activated by RTP. As a result of this, as shown in FIG. 13, the source electrode 131 and the drain electrode 141 are formed in a self-aligned manner with the gate electrode 151 interposed in between in the second direction in the memory cell region 2, and with the extension regions 111 and 121 interposed in between in the upper portion of the resultant substrate 10. The impurity concentration commonly of the source electrode 131 and the drain electrode 141 is higher than that commonly of the extension regions 111 and 121. In addition, the source region 13x and the drain region 14x are formed with the gate electrode 15x interposed in between in the second direction in the peripheral circuit region 5, and with the extension regions 11x and 12x interposed in between in the upper portion of the resultant substrate 10. The impurity concentration commonly of the source electrode 13x and the drain electrode 14x is higher than that commonly of the extension regions 11x and 12x.

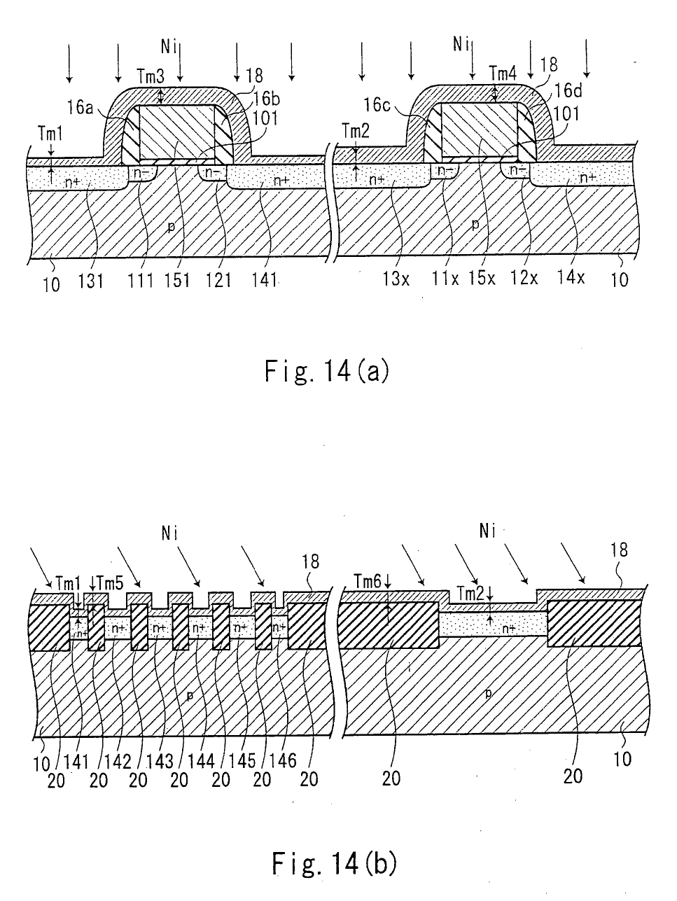

Thereafter, in the salicide process, particles of a metal such as Ni are attached to the entire surface of the wafer in a direction, which is diagonal to the top surface of the substrate 10, and whose horizontal component is parallel to the first direction, as shown in FIGS. 14A and 14B. At this time, a shadowing effect occurs. In the case of the shadowing effect, the metallic particles are hard to be attached to parts overshadowed behind the element-separation insulating films 20 which protrude upwards. In the memory cell region 2, the width W1 commonly of the first element regions is smaller, and the overshadowed parts are relatively larger in area. For this reason, the shadowing effect is conspicuous, and thus the metallic particles are hard to be attached to the top surface. On the other hand, in the peripheral circuit region 5, the width W2 commonly of the second element regions is larger, and the overshadowed parts are relatively smaller in area. For this reason, the shadowing effect is less influential, and thus the metallic particles are easy to be attached to the top surface. This difference between the widths W1 and W2 makes it possible to deposit a metallic film 18 with a film thickness Tm1, for example, of 5 nm to 15 nm on the top surface of each of the first element regions in the memory cell region 2, and to deposit a metallic film 18 with a film thickness Tm2, which is larger than the film thickness Tm1, on the top surface of each of the second element regions in the peripheral circuit regions 5. The film thickness Tm2 is, for example, 10 nm to 30 nm. In addition, a metallic film 18 is deposited in a film thickness Tm3 on the top of the gate electrode 151, and a metallic film 18 is deposited in a film thickness Tm4 on the top of the gate electrode 15x. The film thicknesses Tm3 and Tm4 are approximately equal to the film thickness Tm2 commonly of each of the second element regions in the peripheral circuit region 5.

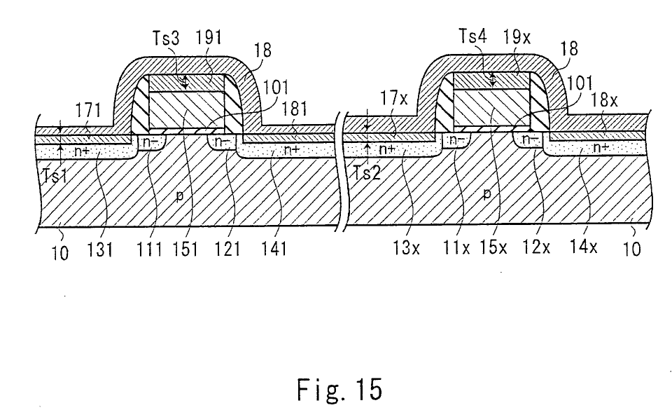

After that, a thermal process is applied to the resultant substrate 10 at a temperature (in a range of 250□ to 700□) which causes the salicide reaction. Thus, the resultant substrate 10 and the metallic film 18 are caused to react on each other. By this reaction, the metallic compound films 171 and 181 each with the film thickness Ts1, for example, of 2 nm to 20 are formed respectively on upper portions of the source region 131 and the drain region 141 in each of the first element regions in the memory cell region 2, as shown in FIG. 15. On the other hand, in each of the second element regions in the peripheral circuit region 5, the film thickness Tm2 of the metallic film 18 is larger than the film thickness Tm1 of the metallic film 18 in the first element region. For this reason, the metallic compound films 17x and 18x each with the film thickness Ts2, which is larger than the film thickness Ts1 commonly of the metallic compound films 171 and 181, are formed respectively on upper portions of the source electrode 13x and the drain electrode 14x. The film thickness Ts2 is, for example, 5 nm to 30 nm. Simultaneously, the gate electrodes 151 and 15x are caused to react on the metal film 18 by thermal processing. The salicide reaction of polycrystalline Si of the gate electrodes 151 and 15x on the metallic film 18 is faster than the salicide reaction of the polycrystalline Si of the gate electrodes 151 and 15x on crystalline Si of the substrate 10. By this reaction, the metallic compound films 191 and 19x respectively with the film thicknesses Ts3 and Ts4 are formed respectively on the gate electrodes 151 and 15x. The film thickness Ts3 is larger than the film thickness Ts1 commonly of the metallic compound films 171 and 181, and the film thickness Ts4 is larger than the film thickness Ts2 commonly of the metallic compound films 17x and 18x. In addition, the film thicknesses Ts3 and Ts4 are approximately equal to each other, and are 10 nm to 40 nm, for example. Thereafter, Si and unreacted parts of the metallic film 18 are removed from the resultant substrate 10. Interlayer dielectric is deposited, and interconnections thereof are formed, depending on the necessity. Thus, the semiconductor device as shown in FIG. 1 can be realized.

As described above, the method of manufacturing a semiconductor device according to this embodiment of the present invention makes it possible to simultaneously form the metallic compound films 171 and 181 each with the film thickness Ts1 in the memory cell region 2 as well as the metallic compound films 17x and 18x each with the film thickness Ts2 in the peripheral circuit region 5, the film thicknesses Ts1 and Ts2 being different from each other. As a result, the salicide process in the memory cell region 2 and the salicide process in the peripheral circuit region 5 do not have to be carried out separately. In addition, the method of manufacturing a semiconductor device according to the present invention eliminates the necessity of performing a step of forming a protection film in order that no metallic compound film may be formed in any one of the memory cell region 2 and the peripheral circuit region 5. Accordingly, the method of manufacturing a semiconductor device according to the present invention makes it possible to inhibit yields from being reduced, and to provide semiconductor devices economically.

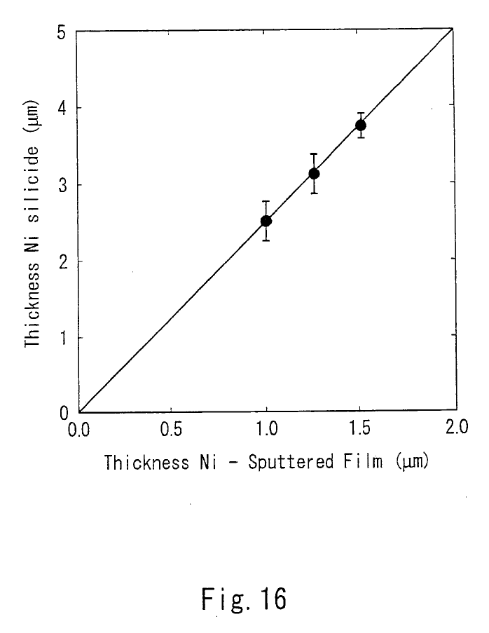

FIG. 16 shows relationships among the film thicknesses Tm1, Tm2, the film thicknesses Ts1 and Ts2. Tm1 and Tm2 respectively denote the film thicknesses of the metallic films 18 and 18 which are obtained when Ni is sputtered as shown in FIGS. 14A and 14B. Ts1 denotes the film thickness commonly of the metallic compound films 171 and 181 which are obtained after the thermal process is carried out as shown in FIG. 15. Ts2 denotes the film thickness commonly of the metallic compound films 17x and 18x which are obtained after the thermal process is carried out as shown in FIG. 15. It can be leaned from FIG. 16 that, when the film thicknesses Tm1 and Tm2 respectively of the metallic films 18 and 18 are thicker, the metallic compound films 171 and 181 are formed in a larger film thickness Ts1, and the metallic compound films 17x and 18x are formed in a larger film thickness Ts2.

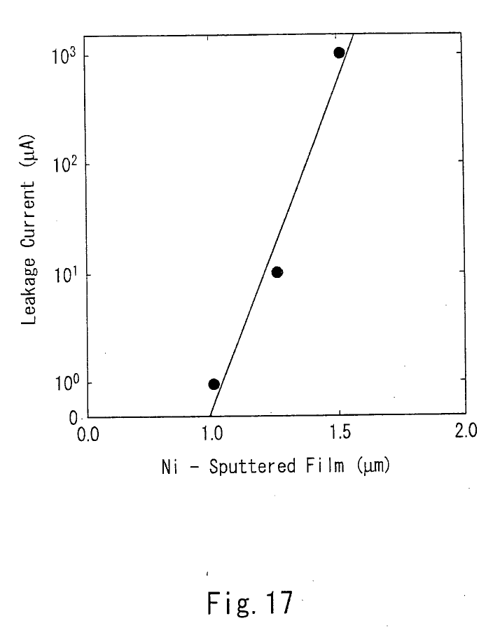

FIG. 17 shows a relationship among Tm1, Tm2 and the leakage current stemming from the junction. Tm1 and Tm2 respectively denotes the film thicknesses of the metallic films 18 and 18 which are obtained when Ni is sputtered as shown in FIGS. 14(a) and 14(b). It can be learned that, the smaller the film thicknesses Tm1 and Tm2 respectively of the metallic films 18 and 18 are, the smaller the leakage current stemming from the junction is.

As described above, the present invention has been described on the basis of this embodiment. It should not be understood, however, that the descriptions and drawings which constitute parts of this disclosure limit the present invention. From this disclosure, various alternative embodiments, examples and applied techniques are clear to those skilled in this art.

As another embodiment of the present invention, for example, the film thickness Ts1 commonly of the metallic compound films 171 and 181 and the film thickness Ts2 commonly of the metallic compound films 17x and 18x may be made different from each other by making conditions for the thermal process different between the memory cell region 2 and the peripheral circuit region 5 when the thermal process for causing the salicide reaction as shown in FIG. 15 is carried out. In this case, for example, a local heating process of heating by irradiating laser beams by use of a laser irradiation system is utilized. The heating by use of the laser beams makes it possible to change the diameter of beams arbitrarily. In addition, this makes it possible to heat an entire chip, and also to heat only a particular area in a chip. In the case of the local heating process, for example, the metallic compound films 171 and 181 are formed thinner in the memory cell region 2 shown in FIG. 1 by heating the region at a relatively low temperature for a relatively short time. On the other hand, the metallic compound films 17x and 18x are formed thicker in the peripheral circuit region 5 by heating the region at a higher temperature for a longer time.

In the conventional practice, the heating process for causing salicide reaction employs a lamp heating scheme or a heater heating scheme, and thus heats the entire surface of a wafer evenly, hence causing the salicide reaction. By contrast, the local change of conditions for the thermal process makes it possible to form the metallic compound films 171 and 181 in the film thickness Ts1 which is different from the film thickness Ts2 in which the metallic compound films 17x and 18x are formed.

The element-separation insulating films 20 are caused to protrude from the surface of the substrate 10 during CMP as shown in FIG. 9. However, the element-separation insulating films 20 may be evened at the same height as the substrate 10 instead of causing the element-separation insulating films 20 to protrude therefrom, if conditions for the thermal process are changed locally. In addition, the sputtering may be applied to the substrate 10 in a direction perpendicular to the substrate 10, although the difference between the film thicknesses can be made larger if the sputtering is applied to the substrate 10 in the direction diagonal to the substrate 10 as shown in FIGS. 14A and 14B.

Moreover, the metallic compound films 171 and 181 may be formed in the film thickness Ts1 which is different from the film thickness Ts2 in which the metallic compound films 17x and 18x are formed, by making material and characteristics (stress) of the element-separation insulating films 20 between the memory cell region 2 and the peripheral circuit region 5. For example, stress for inhibiting the silicide reaction in the memory cell region 2 may be applied to the element regions. To this end, a material with large film stress may be used for the element-separation insulating films 20. Otherwise, the film stress may be changed by means of a material which is the same as the material used in this embodiment of the present invention and by subsequently applying a thermal process thereto after the elements are separated from one another. The material for the element-separation insulating films 20 may be selected according to required characteristics depending on the necessity. In the subsequent sputtering, metallic particles may be adhered to the substrate 10 in a direction diagonal to the substrate 10, or in a direction perpendicular to the substrate 10.

Stress making it hard to grow silicide is applied to the element regions, which are narrow by nature. Change in the film thickness of the metallic films 20 makes it possible to increase the difference between the film thickness commonly of the metallic compound films 171 and 181 and the film thickness commonly of the metallic compound films 17x and 18x.

It is needless to say that the present invention includes various embodiments and the like which have not been described here. As a result, the technological scope of the present invention are determined with only matters to define the invention as recited in appropriate claims on the basis of the foregoing descriptions.

What is claimed is:

1. A semiconductor device comprising:
a semiconductor substrate;
a SRAM area formed in the semiconductor substrate, the SRAM area comprising a first transistor with a first source region and a first drain region, wherein a metallic compound film having a first thickness is formed on each of the first source and first drain regions; and
a logic circuit area formed in the semiconductor substrate, the logic circuit area comprising a second transistor with a second source region and a first drain region, wherein a metallic compound film having a second thickness is formed on each of the second source and second drain regions, wherein the second thickness is greater than the first thickness.

2. The semiconductor device according to claim 1, wherein the metallic compound film is silicide film.

3. The semiconductor device according to claim 1, wherein the semiconductor circuit is used for a CPU or a DSP.

4. The semiconductor device according to claim 1, wherein the first transistor comprises a first gate electrode and a metallic compound film having a third thickness formed on the first gate electrode, the third thickness greater than the first thickness.

5. The semiconductor device according to claim 1, the semiconductor circuit further comprising;
a first element region formed in the SRAM area between a first element separation insulating films and a second element separation insulating film; and
a second element region formed in the logic circuit area, between a third element separation insulating film and a fourth element separation insulating film.

6. The semiconductor device according to claim 1, wherein the first and second element separation films extend along a first direction for a greater distance than either the third or the fourth element separation insulating films.

7. The semiconductor device according to claim 5, the wherein the first source and first drain regions are in the first element region.

8. The semiconductor device according to claim 7, wherein the second source and second drain regions are in the second element region.

9. The semiconductor device according to claim 8, wherein the first element region has a first width, the second element region has a second width, the second width greater than the first width.

10. The semiconductor device according to claim 1, wherein the first transistor has a first gate length comprising a distance between the first source region and the first drain region in a second direction orthogonal to the first direction, the second transistor has a second gate length comprising a distance between the second source region and the second drain region in the second direction orthogonal to the first direction and the second gate length is as long as the first gate length.

11. A method of manufacturing a semiconductor device, comprising:
forming a first transistor in a first element region of the semiconductor device, the first transistor having a first source region and a first drain region;
forming a second transistor in a second element region of the semiconductor device, the second transistor having a second source region and a second drain region; and
simultaneously forming a metallic compound film on an upper region of each of the first source region, the first drain region, the second source region and the second drain region such that a thickness of the metallic compound film in the first source region and first drain region is greater than a thickness of the metallic compound film in the second source region and the second drain region.

12. The method of manufacturing a semiconductor device according to claim 11, comprising:
forming a set of element separation insulating films films in a substrate such that a portion of each of the set of element separation insulating films is higher than a surface of the substrate, and thereby defining element regions in parts of the top surface of the substrate, the first element region having a first width and lying between a first and second element separation insulating film and the second element region having a second width and lying between a third and a fourth element separation insulating film;
depositing a metallic film on each of the first drain region, the second drain region, the first source region and the second drain region in a first direction forming an angle with the surface of the substrate; and
causing the substrate and the metallic film to react on each other by thermal processing to form the metallic compound films,

13. The method of manufacturing a semiconductor device according to claim 12, wherein the second width is greater than the first width along a second direction and the metallic film is deposited such that a layer of metallic film in the first element region is thinner than a layer of metallic film in the second element region.

14. The method of manufacturing a semiconductor device according to claim 13, wherein the first direction has a horizontal component parallel to the first direction.

15. The method of manufacturing a semiconductor device according claim 11, comprising, causing a first condition to exist with respect to the first element region and a second condition to exist with respect to the second element region during the thermal processing.

16. The method of manufacturing a semiconductor device according claim 11, wherein the first element separation insulating film has a first film stress for inhibiting the reaction of the substrate and the metallic film in the first source region and first drain region.

17. The method of manufacturing a semiconductor device according claim 11, comprising applying a first film stress to the first element region to inhibit the reaction of the substrate and the metallic film in the first source region and first drain region.

18. The method of manufacturing a semiconductor device according to claim 11, wherein the first element region is in an SRAM area and the second element region is in a logic area region.

19. The method of manufacturing a semiconductor device according to claim 18, wherein the metallic compound film is silicide film.

20. A method of manufacturing a semiconductor device, comprising:
forming a set of element separation insulating films in a substrate such that a portion of each of the set of element separation insulating films is higher than a surface of the substrate, a first element region an SRAM area of the semiconductor device and the second element region in a logic area of the semiconductor device, the first element region having a first width and lying between a first and second element separation insulating film and the second element region having a second width and lying between a third and a fourth element separation insulating film, the second width being greater than the first width in a first direction;
forming a first gate electrode extending in the first direction in the first element region and a second gate electrode extending in the first direction in the second element region;
forming a first transistor in a first element region of the semiconductor device, the first transistor having a first source region and a first drain region;
forming a second transistor in a second element region of the semiconductor device, the second transistor having a second source region and a second drain region;
depositing a metallic film on each of the gate electrodes, source regions and drain regions in a direction forming an angle with the surface of the substrate; and
simultaneously forming a metallic compound film on the first gate electrode, second gate electrode and on an upper region of each of the first source region, the first drain region, the second source region and the second drain region such that a first thickness of the metallic compound film in the first source region and first drain region is greater than a second thickness of the metallic compound film in the second source region and the second drain region and a third thickness of the of the metallic compound film on the first gate electrode and the second gate electrode is thicker than either the first thickness or the second thickness.
